(19) United States
(12) Patent Application Publication
(10) Pub. No.: US 2025/0331208 A1
(43) Pub. Date: Oct. 23, 2025

(54) SEMICONDUCTOR DEVICE

(71) Applicant: Mitsubishi Electric Corporation, Tokyo (JP)

(72) Inventors: Kosuke SAKAGUCHI, Tokyo (JP); Kenji HARADA, Tokyo (JP)

(73) Assignee: Mitsubishi Electric Corporation, Tokyo (JP)

(21) Appl. No.: 19/052,251

(22) Filed: Feb. 12, 2025

(30) Foreign Application Priority Data
Apr. 17, 2024 (JP) 2024-066761

(51) Int. Cl. H10D 12/00; H10D 62/10

(52) U.S. Cl. CPC H10D 12/481; H10D 62/127

(57) ABSTRACT

A semiconductor device includes an emitter electrode arranged on a cell region, a gate wiring arranged outside the emitter electrode, and a gate finger wiring having one end connected to the gate wiring and extending on the cell region. The emitter electrodes adjacent to each other with the gate finger wiring interposed between them are connected by an emitter electrode coupling portion arranged in a region between another end of the gate finger wiring and the gate wiring. In the semiconductor substrate, a first active trench gate intersecting the gate finger wiring and a second active trench gate that leads out the first active trench gate located below the emitter electrode coupling portion to below the gate finger wiring are formed.

### BACKGROUND OF THE INVENTION

### Field of the Invention

The present disclosure relates to a semiconductor device.

### Description of the Background Art

There is known a vertical semiconductor device that includes an electrode on each of a front surface side and a back surface side, and is energized in a vertical direction, that is, a direction connecting the front surface and the back surface. For example, Japanese Patent Application Laid-Open No. 2006-210519 discloses a configuration in which an electrode on a front surface side of a vertical semiconductor device (hereinafter referred to as “front surface electrode”) is divided into a plurality of parts by a gate liner which is a control wiring for transmitting a gate signal to a gate electrode.

In the semiconductor device in which a front surface electrode is divided into a plurality of parts by a gate liner as in Japanese Patent Application Laid-Open No. 2006-210519, flowing current becomes unbalanced, and short-circuit withstand capacity is likely to be lowered. However, if the gate liner is provided to bypass the front surface electrode such that the front surface electrode is not divided, there is a concern about a delay of a gate signal.

### SUMMARY

An object of the present disclosure is to provide a semiconductor device capable of preventing lowering in short-circuit withstand capacity and a delay of a gate signal.

A semiconductor device according to the present disclosure includes a plurality of active trench gates formed in a cell region of a semiconductor substrate, an emitter electrode arranged on the cell region, a gate wiring arranged outside the emitter electrode and electrically connected to a plurality of the active trench gates, and a gate finger wiring electrically connected to the gate wiring and extending on the cell region. One end of the gate finger wiring is connected to the gate wiring, and another end of the gate finger wiring does not reach the gate wiring. The emitter electrodes adjacent to each other with the gate finger wiring interposed between them are electrically connected to each other through an emitter electrode coupling portion arranged in a region between the another end of the gate finger wiring and the gate wiring. The active trench gate includes a first active trench gate extending in a first direction intersecting an extending direction of the gate finger wiring, and a second active trench gate connected to the first active trench gate located below the emitter electrode coupling portion, extending in a second direction parallel to the extending direction of the gate finger wiring, and extended to below the gate finger wiring or the gate wiring.

According to the semiconductor device of the present disclosure, it is possible to prevent lowering in short-circuit withstand capacity and a delay of a gate signal.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIGS. 1 and 2 are plan views of a chip of a semiconductor device according to a first preferred embodiment;

FIG. 3 is a plan view of an IGBT region of the semiconductor device according to the first preferred embodiment;

FIGS. 4 and 5 are cross-sectional views of the IGBT region of the semiconductor device according to the first preferred embodiment;

FIG. 6 is a plan view of a diode region of the semiconductor device according to the first preferred embodiment;

FIGS. 7 and 8 are cross-sectional views of the diode region of the semiconductor device according to the first preferred embodiment;

FIG. 9 is a cross-sectional view of a boundary between the IGBT region and the diode region of the semiconductor device according to the first preferred embodiment;

FIG. 10 is a plan view of the vicinity of an emitter electrode coupling region of the semiconductor device according to the first preferred embodiment;

FIG. 11 is a cross-sectional view of the vicinity of the emitter electrode coupling region of the semiconductor device according to the first preferred embodiment;

FIG. 12 is a plan view of the vicinity of the emitter electrode coupling region of the semiconductor device according to the first preferred embodiment;

FIG. 13 is a diagram illustrating a shape of the emitter electrode coupling portion of the semiconductor device according to a second preferred embodiment;

FIG. 14 is a plan view of the vicinity of the emitter electrode coupling region of the semiconductor device according to a third preferred embodiment;

FIG. 15 is a plan view of the vicinity of the emitter electrode coupling region of the semiconductor device according to a fourth preferred embodiment;

FIG. 16 is a plan view of the vicinity of the emitter electrode coupling region of the semiconductor device according to a fifth preferred embodiment;

FIG. 17 is a cross-sectional view of the vicinity of the emitter electrode coupling region of the semiconductor device according to the fifth preferred embodiment;

FIG. 18 is a plan view of the vicinity of the emitter electrode coupling region of the semiconductor device according to a sixth preferred embodiment;

FIG. 19 is a cross-sectional view of the vicinity of the emitter electrode coupling region of the semiconductor device according to the sixth preferred embodiment;

FIG. 20 is a plan view of the vicinity of the emitter electrode coupling region of the semiconductor device according to a seventh preferred embodiment;

FIG. 21 is a cross-sectional view of the vicinity of the emitter electrode coupling region of the semiconductor device according to the seventh preferred embodiment;

FIG. 22 is a plan view of the vicinity of the emitter electrode coupling region of the semiconductor device according to an eighth preferred embodiment;

FIG. 23 is a cross-sectional view of the vicinity of the emitter electrode coupling region of the semiconductor device according to the eighth preferred embodiment;

FIG. 24 is a plan view of the vicinity of the emitter electrode coupling region of the semiconductor device according to a ninth preferred embodiment;

FIG. 25 is a plan view of the vicinity of the emitter electrode coupling region of the semiconductor device according to a tenth preferred embodiment;

FIG. 26 is a cross-sectional view of the vicinity of the emitter electrode coupling region of the semiconductor device according to an eleventh preferred embodiment; and

FIG. 27 is a plan view of the chip of the semiconductor device according to a twelfth preferred embodiment.

### DESCRIPTION OF THE PREFERRED EMBODIMENTS

In description below, n and p represent a conductivity type of a semiconductor, and in the present disclosure, a first conductivity type is described as an n type and a second conductivity type is described as a p type, but the first conductivity type may be described as a p type and the second conductivity type may be described as an n type. Further, n-indicates that impurity concentration is lower than that of n, and n⁺ indicates that impurity concentration is higher than that of n. Similarly, p indicates that impurity concentration is lower than that of p, and p⁺ indicates that impurity concentration is higher than that of p.

Further, degree of impurity concentration of each region is defined by peak concentration. That is, a region having high (or low) impurity concentration means a region having high (or low) impurity peak concentration.

### First Preferred Embodiment

Hereinafter, a configuration of a semiconductor device according to a first preferred embodiment will be described. A metal oxide semiconductor field effect transistor (MOSFET), an insulated gate bipolar transistor (IGBT), a reverse conducting IGBT (RC-IGBT), and the like are assumed as a semiconductor element included in the semiconductor device, but here, the semiconductor element is assumed to be an RC-IGBT.

A material of the semiconductor element may be silicon (Si) or a wide band gap semiconductor such as silicon carbide (SiC). A semiconductor device formed using a wide band gap semiconductor is excellent in operation at high voltage, large current, and high temperature as compared with a semiconductor device using silicon. Examples of the wide bandgap semiconductor include a gallium nitride (GaN)-based material and diamond in addition to silicon carbide.

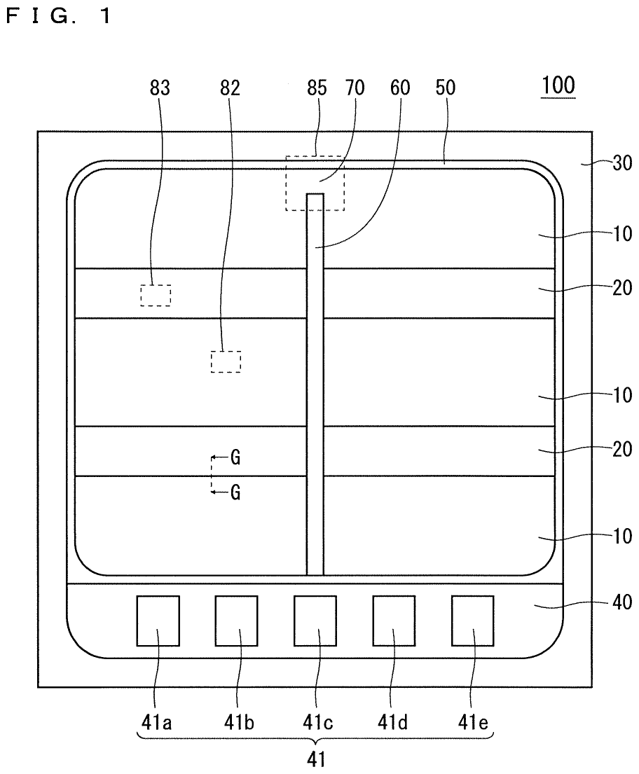

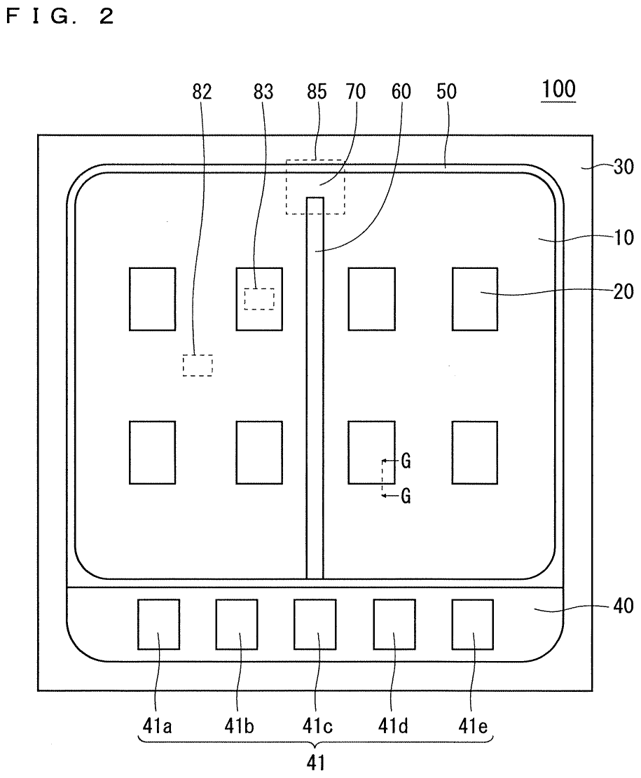

FIG. 1 is a plan view illustrating a semiconductor device that is an RC-IGBT. FIG. 2 is a plan view illustrating a semiconductor device that is an RC-IGBT having another configuration. A semiconductor device 100 illustrated in FIG. 1 is provided with an IGBT region 10 and a diode region 20 arranged in a stripe shape, and may be simply referred to as a “stripe type”. The semiconductor device 100 illustrated in FIG. 2 is provided with a plurality of the diode regions 20 in a longitudinal direction and a lateral direction, and the IGBT region 10 is provided around the diode region 20, and may be simply referred to as an “island type”.

### (1) Overall Planar Structure of Stripe Type

In FIG. 1, the semiconductor device 100 includes the IGBT region 10 and the diode region 20 in one semiconductor device. The IGBT region 10 and the diode region extend from one end side to another end side of the semiconductor device 100, and are alternately provided in a stripe shape in a direction orthogonal to an extending direction of the IGBT region 10 and the diode region 20. FIG. 1 illustrates three of the IGBT regions and two of the diode regions in a configuration where all the diode regions 20 are sandwiched between the IGBT regions 10. However, the numbers of the IGBT regions 10 and the diode regions 20 are not limited to these, and the number of the IGBT regions 10 may be three or more or three or less, and the number of the diode regions 20 may be two or more or two or less. Further, the configuration may be such that the IGBT region 10 and the diode region 20 in FIG. 1 are interchanged in location, or all the IGBT regions 10 are sandwiched between the diode regions 20. Further, the configuration may be such that the IGBT region 10 and the diode region 20 are provided adjacent to each other one by one.

As illustrated in FIG. 1, a pad region 40 is provided adjacent to a lower side of the IGBT region 10 in the drawing. The pad region 40 is a region where a control pad 41 for controlling the semiconductor device 100 is provided. The IGBT region 10 and the diode region 20 are collectively referred to as a cell region. As will be described later, an emitter electrode of an RC-IGBT is arranged on the cell region of the semiconductor device 100.

In the present preferred embodiment, a gate wiring region 50 in which a gate wiring for transmitting a gate signal for controlling energization of the semiconductor device 100 is arranged is provided around the cell region. Further, a gate finger wiring region 60 in which a gate finger wiring connected to a gate wiring is arranged is provided so as to enter the cell region from one side (side closer to the pad region 40) of the gate wiring region 50 and extend. A tip of the gate finger wiring region 60 does not reach a side opposite to the gate wiring region 50 (side far from the pad region 40). That is, one end of a gate finger wiring 61 is connected to a gate wiring 51, but another end is not connected to the gate wiring 51.

Therefore, the gate finger wiring region 60 does not completely divide the IGBT region 10, and a gap exists between a tip of the gate finger wiring region 60 and the gate wiring region 50. Since a gate finger wiring is formed on the same layer as an emitter electrode, the emitter electrode is partitioned by the gate finger wiring. However, portions of the emitter electrode adjacent to each other by sandwiching the gate finger wiring are connected to each other via an emitter electrode coupling region 70 which is a region between a tip of the gate finger wiring region 60 and the gate wiring region 50. The gate wiring and the gate finger wiring will be described in detail in “(6) Structure of gate wiring and gate finger wiring” described later.

A termination region 30 is provided around a region that combines the cell region and the pad region 40 in order to maintain withstand voltage of the semiconductor device 100. A known withstand voltage holding structure can be appropriately selected and provided in the termination region 30. The withstand voltage holding structure may be configured by, for example, providing a field limiting ring (FLR) surrounding a region that combines the cell region and the pad region 40 on a p-type termination well layer of a p-type semiconductor or a variation of lateral doping (VLD) surrounding a region that combines the cell region and the pad region 40 on a p-type termination well layer with a concentration gradient on a first main surface side which is a front surface side of the semiconductor device 100, and the number of ring-shaped p-type termination well layers used for the FLR and concentration distribution used for the VLD may be appropriately selected according to withstand voltage design of the semiconductor device 100. Further, a p-type termination well layer may be provided over substantially the entire pad region 40, and an IGBT cell or a diode cell may be provided in the pad region 40.

The control pad 41 may be, for example, a current sense pad 41a, a Kelvin emitter pad 41b, a gate pad 41c, and temperature sense diode pads 41d and 41e. The current sense pad 41a is a control pad for detecting current flowing through a cell region of the semiconductor device 100, and is a control pad electrically connected to a part of IGBT cells or diode cells in the cell region such that, when current flows through the cell region of the semiconductor device 100, current ranging from fractions to several tens of thousandths of current flowing through the entire cell region flows.

The Kelvin emitter pad 41b and the gate pad 41c are control pads to which gate drive voltage for controlling on and off of the semiconductor device 100 is applied. The Kelvin emitter pad 41b is electrically connected to a p-type base layer and an n⁺-type emitter layer of an IGBT cell, and the gate pad 41c is electrically connected to a gate trench electrode of the IGBT cell. The Kelvin emitter pad 41b and the p-type base layer may also be electrically connected via a p⁺-type contact layer. The temperature sense diode pads 41d and 41e are control pads electrically connected to an anode and a cathode of a temperature sense diode provided in the semiconductor device 100. Voltage between an anode and a cathode of a temperature sense diode (not illustrated) provided in the cell region is measured to measure temperature of the semiconductor device 100.

### (2) Overall Planar Structure of Island Type

In FIG. 2, the semiconductor device 100 includes the IGBT region 10 and the diode region 20 in one semiconductor device. A plurality of the diode regions 20 are arranged side by side in a longitudinal direction and a lateral direction in the semiconductor device, and the diode region 20 is surrounded by the IGBT region 10. That is, a plurality of the diode regions 20 are provided in an island shape in the IGBT region 10. FIG. 2 illustrates a configuration in which the diode regions 20 are provided in a matrix of four columns in a left-right direction in the diagram and two rows in an upper limit direction in the diagram. However, the number and arrangement of the diode regions 20 are not limited to this, and one or a plurality of the diode regions 20 may be provided in the IGBT region in an interspersed manner, and each of the diode regions 20 may be surrounded by the IGBT region 10.

As illustrated in FIG. 2, the pad region 40 is provided adjacent to a lower side in the diagram of the IGBT region 10. The pad region 40 is a region where a control pad 41 for controlling the semiconductor device 100 is provided. The IGBT region 10 and the diode region 20 are collectively referred to as a cell region.

In a case where the structure of an RC-IGBT is an island type, the gate wiring region 50 in which a gate wiring is arranged is provided around the cell region. Further, the gate finger wiring region 60 in which a gate finger wiring is arranged is provided so as to enter the cell region from one side of the gate wiring region 50 and extend. The emitter electrode coupling region 70 is provided in a gap between a tip of the gate finger wiring region 60 and the gate wiring region 50.

A termination region 30 is provided around a region that combines the cell region and the pad region 40 in order to maintain withstand voltage of the semiconductor device 100. A known withstand voltage holding structure can be appropriately selected and provided in the termination region 30. The withstand voltage holding structure may be configured by, for example, providing a field limiting ring (FLR) surrounding a region that combines the cell region and the pad region 40 on a p-type termination well layer of a p-type semiconductor or a variation of lateral doping (VLD) surrounding a region that combines the cell region and the pad region 40 on a p-type termination well layer with a concentration gradient on a first main surface side which is a front surface side of the semiconductor device 100, and the number of ring-shaped p-type termination well layers used for the FLR and concentration distribution used for the VLD may be appropriately selected according to withstand voltage design of the semiconductor device 100. Further, a p-type termination well layer may be provided over substantially the entire pad region 40, and an IGBT cell or a diode cell may be provided in the pad region 40.

The control pad 41 may be, for example, a current sense pad 41a, a Kelvin emitter pad 41b, a gate pad 41c, and temperature sense diode pads 41d and 41e. The current sense pad 41a is a control pad for detecting current flowing through a cell region of the semiconductor device 100, and is a control pad electrically connected to a part of IGBT cells or diode cells in the cell region such that, when current flows through the cell region of the semiconductor device 100, current ranging from fractions to several tens of thousandths of current flowing through the entire cell region flows.

The Kelvin emitter pad 41b and the gate pad 41c are control pads to which gate drive voltage for controlling on and off of the semiconductor device 100 is applied. The Kelvin emitter pad 41b is electrically connected to a p-type base layer and an n⁺-type emitter layer of an IGBT cell, and the gate pad 41c is electrically connected to a gate trench electrode of the IGBT cell. The Kelvin emitter pad 41b and the p-type base layer may also be electrically connected via a p⁺-type contact layer. The temperature sense diode pads 41d and 41e are control pads electrically connected to an anode and a cathode of a temperature sense diode provided in the semiconductor device 100. Voltage between an anode and a cathode of a temperature sense diode (not illustrated) provided in the cell region is measured to measure temperature of the semiconductor device 100.

### (3) Example of Structure of IGBT Region 10

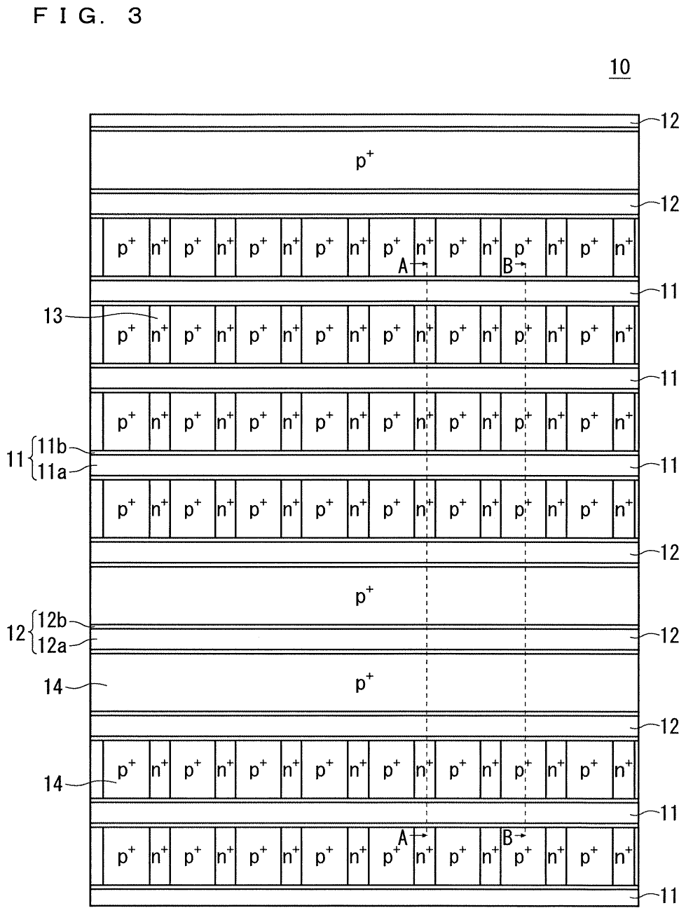

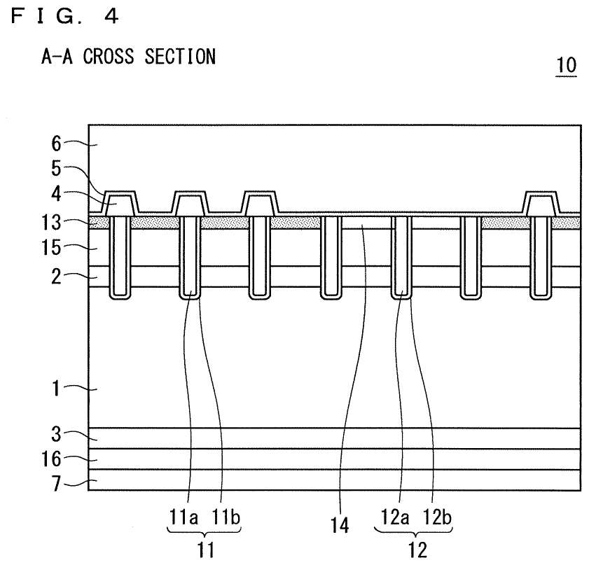

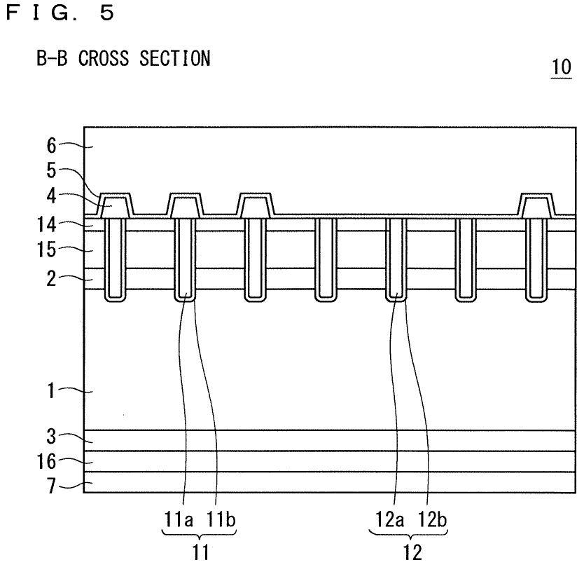

FIG. 3 is a partially enlarged plan view illustrating a configuration of an IGBT region of a semiconductor device that is an RC-IGBT. Further, FIGS. 4 and 5 are cross-sectional views illustrating a configuration of an IGBT region of a semiconductor device that is an RC-IGBT. FIG. 3 illustrates a region surrounded by a broken line 82 in the semiconductor device 100 illustrated in FIG. 1 or 2 in an enlarged manner. FIG. 4 is a cross-sectional view taken along broken line A-A of the semiconductor device 100 illustrated in FIG. 3, and FIG. 5 is a cross-sectional view taken along broken line B-B of the semiconductor device 100 illustrated in FIG. 3.

As illustrated in FIG. 3, an active trench gate 11 and a dummy trench gate 12 are provided in a stripe shape in the IGBT region 10. In the semiconductor device 100 of FIG. 1, the active trench gate 11 and the dummy trench gate 12 extend in a longitudinal direction of the IGBT region 10, and the longitudinal direction of the IGBT region 10 is a longitudinal direction of the active trench gate 11 and the dummy trench gate 12. On the other hand, in the semiconductor device 100 of FIG. 2, the longitudinal direction and a lateral direction are not particularly distinguished in the IGBT region 10, but a left-right direction in the diagram may be the longitudinal direction of the active trench gate 11 and the dummy trench gate 12, and a vertical direction in the diagram may be the longitudinal direction of the active trench gate 11 and the dummy trench gate 12.

The active trench gate 11 is configured such that a gate trench electrode 11a is provided with a gate trench insulating film 11b in a trench formed in a semiconductor substrate. The dummy trench gate 12 is configured such that a dummy trench electrode 12a is provided with a dummy trench insulating film 12b in a trench formed in a semiconductor substrate. The gate trench electrode 11a of the active trench gate 11 is electrically connected to the gate pad 41c. The dummy trench electrode 12a of the dummy trench gate 12 is electrically connected to an emitter electrode provided on the first main surface of the semiconductor device 100.

An n⁺-type emitter layer 13 is provided in contact with the gate trench insulating film 11b on both sides in a width direction of the active trench gate 11. The n⁺-type emitter layer 13 is a semiconductor layer containing, for example, arsenic or phosphorus as an n-type impurity, and concentration of the n-type impurity is 1.0E+17/cm³ to 1.0E+20/cm³. Further, the n⁺-type emitter layer 13 is provided alternately with a p⁺-type contact layer 14 along an extending direction of the active trench gate 11. The p⁺-type contact layer 14 is also provided between two adjacent ones of the dummy trench gates 12. The p⁺-type contact layer 14 is a semiconductor layer containing, for example, boron or aluminum as a p-type impurity, and concentration of the p-type impurity is 1.0E+15/cm³ to 1.0E+20/cm³.

As illustrated in FIG. 3, in the IGBT region 10 of the semiconductor device 100, three of the dummy trench gates 12 are arranged next to three of the active trench gates 11, and three of the active trench gates 11 are arranged next to three of the dummy trench gates 12. The IGBT region 10 has a configuration in which a set of the active trench gates 11 and a set of the dummy trench gates 12 are alternately arranged as described above. In FIG. 3, the number of the active trench gates 11 included in one set of the active trench gates 11 is three, but may be one or more. Further, the number of the dummy trench gates 12 included in one set of the dummy trench gates 12 may be one or more, and the number of the dummy trench gates 12 may be zero. That is, all trenches provided in the IGBT region may be the active trench gate 11.

FIG. 4 is a cross-sectional view of the semiconductor device 100 taken along broken line A-A in FIG. 3, and is a cross-sectional view of the IGBT region 10. The semiconductor device 100 includes an n⁻-type drift layer 1 including a semiconductor substrate. The n⁻-type drift layer 1 is a semiconductor layer containing, for example, arsenic or phosphorus as an n-type impurity, and concentration of the n-type impurity is 1.0E+12/cm³ to 1.0E+15/cm³. A semiconductor substrate is a range from the n⁺-type emitter layer 13 and the p⁺-type contact layer 14 to a p-type collector layer 16. In FIG. 4, an upper end in the diagram of the n⁺-type emitter layer 13 and the p⁺-type contact layer 14 is referred to as a first main surface of the semiconductor substrate, and a lower end in the diagram of the p-type collector layer 16 is referred to as a second main surface of the semiconductor substrate. The first main surface of the semiconductor substrate is a main surface on the front surface side of the semiconductor device 100, and the second main surface of the semiconductor substrate is a main surface on the back surface side of the semiconductor device 100. The semiconductor device 100 includes the n⁻-type drift layer 1 between the first main surface and the second main surface facing the first main surface in the IGBT region 10 that is the cell region.

As illustrated in FIG. 4, in the IGBT region 10, an n-type carrier stored layer 2 having higher concentration of an n-type impurity than the n-type drift layer 1 is provided on a first main surface side of the n-type drift layer 1. The n-type carrier stored layer 2 is a semiconductor layer containing, for example, arsenic or phosphorus as an n-type impurity, and concentration of the n-type impurity is 1.0E+13/cm³ to 1.0E+17/cm³. Note that the semiconductor device 100 may have a configuration in which the n-type carrier stored layer 2 is not provided and the n⁻-type drift layer 1 is provided also in a region of the n-type carrier stored layer 2 illustrated in FIG. 4. By providing the n-type carrier stored layer 2, a conduction loss when current flows in the IGBT region 10 can be reduced. The n-type carrier stored layer 2 and the n⁻-type drift layer 1 may be collectively referred to as a drift layer.

The n-type carrier stored layer 2 is formed by ion-implanting an n-type impurity into a semiconductor substrate constituting the n⁻-type drift layer 1 and then diffusing the implanted an n-type impurity into the semiconductor substrate as the n⁻-type drift layer 1 by annealing.

A p-type base layer 15 is provided on the first main surface side of the n-type carrier stored layer 2. The p-type base layer 15 is a semiconductor layer containing, for example, boron or aluminum as a p-type impurity, and concentration of the p-type impurity is 1.0E+12/cm³ to 1.0E+19/cm³. The p-type base layer 15 is in contact with the gate trench insulating film 11b of the active trench gate 11. On the first main surface side of the p-type base layer 15, the n⁺-type emitter layer 13 is provided in contact with the gate trench insulating film 11b of the active trench gate 11, and the p⁺-type contact layer 14 is provided in a remaining region. The n⁺-type emitter layer 13 and the p⁺-type contact layer 14 constitute the first main surface of the semiconductor substrate. Note that the p⁺-type contact layer 14 is a region having higher concentration of a p-type impurity than the p-type base layer 15, and in a case where it is necessary to distinguish the p⁺-type contact layer 14 and the p-type base layer 15 from each other, they may be referred to individually, and the p⁺-type contact layer 14 and the p-type base layer 15 may be collectively referred to as a p-type base layer.

Further, in the semiconductor device 100, an n-type buffer layer 3 having higher concentration of an n-type impurity than the n⁻-type drift layer 1 is provided on the second main surface side of the n-type drift layer 1. The n-type buffer layer 3 is provided to prevent punch-through of a depletion layer extending from the p-type base layer 15 to the second main surface side when the semiconductor device 100 is in an off state. The n-type buffer layer 3 may be formed by, for example, injecting phosphorus (P) or a proton (H⁺), or may be formed by injecting both phosphorus (P) and a proton (H⁺). Concentration of an n-type impurity in the n-type buffer layer 3 is 1.0E+12/cm³ to 1.0E+18/cm³.

Note that the semiconductor device 100 may have a configuration in which the n-type buffer layer 3 is not provided and the n⁻-type drift layer 1 is also provided in a region of the n-type buffer layer 3 illustrated in FIG. 4. The n-type buffer layer 3 and the n⁻-type drift layer 1 may be collectively referred to as a drift layer.

In the semiconductor device 100, the p-type collector layer 16 is provided on a second main surface side of the n-type buffer layer 3. That is, the p-type collector layer 16 is provided between the n⁻-type drift layer 1 and the second main surface. The p-type collector layer 16 is a semiconductor layer containing, for example, boron or aluminum as a p-type impurity, and concentration of the p-type impurity is 1.0E+16/cm³ to 1.0E+20/cm³. The p-type collector layer 16 constitutes the second main surface of the semiconductor substrate. The p-type collector layer 16 is provided not only in the IGBT region 10 but also in the termination region 30, and a portion provided in the termination region 30 on the p-type collector layer 16 constitutes the p-type termination collector layer 16a. Further, the p-type collector layer 16 may be provided so as to partially protrude from the IGBT region 10 into the diode region 20.

As illustrated in FIG. 4, in the semiconductor device 100, a trench that penetrates the p-type base layer 15 from the first main surface of the semiconductor substrate and reaches the n⁻-type drift layer 1 is formed. The gate trench electrode 11a is provided in the trench with the gate trench insulating film 11b interposed between them to constitute the active trench gate 11. The gate trench electrode 11a faces the n⁻-type drift layer 1 with the gate trench insulating film 11b interposed between them. Further, the dummy trench electrode 12a is provided in the trench with the dummy trench insulating film 12b interposed between them to constitute the dummy trench gate 12. The dummy trench electrode 12a faces the n⁻-type drift layer 1 with the dummy trench insulating film 12b interposed between them. The gate trench insulating film 11b of the active trench gate 11 is in contact with the p-type base layer 15 and the n⁺-type emitter layer 13. When gate drive voltage is applied to the gate trench electrode 11a, a channel is formed in the p-type base layer 15 in contact with the gate trench insulating film 11b of the active trench gate 11.

As illustrated in FIG. 4, an interlayer insulating film 4 is provided on the gate trench electrode 11a of the active trench gate 11. Barrier metal 5 is formed on a region where the interlayer insulating film 4 is not provided on the first main surface of the semiconductor substrate and on the interlayer insulating film 4. The barrier metal 5 may be, for example, a conductor containing titanium (Ti), and may be, for example, titanium nitride or TiSi obtained by alloying titanium and silicon (Si). As illustrated in FIG. 4, the barrier metal 5 is in ohmic contact with the n⁺-type emitter layer 13, the p⁺-type contact layer 14, and the dummy trench electrode 12a, and is electrically connected to the n⁺-type emitter layer 13, the p⁺-type contact layer 14, and the dummy trench electrode 12a. An emitter electrode 6 is provided on the barrier metal 5. The emitter electrode 6 may be formed of, for example, an aluminum alloy such as an aluminum silicon alloy (Al—Si-based alloy), or may be an electrode including a plurality of layers of metal films in which a plating film is formed on an electrode formed of an aluminum alloy by electroless plating or electrolytic plating. The plating film formed by electroless plating or electrolytic plating may be, for example, a nickel (Ni) plating film. Further, in a case where there is a fine region between adjacent ones of the interlayer insulating films 4 or the like and a region where favorable embedding cannot be obtained by the emitter electrode 6, tungsten having better embeddability than the emitter electrode 6 may be arranged in the fine region, and the emitter electrode 6 may be provided on the tungsten. Note that the emitter electrode 6 may be provided on the n⁺-type emitter layer 13, the p⁺-type contact layer 14, and the dummy trench electrode 12a without provision of the barrier metal 5. Further, the barrier metal 5 may be provided only on an n-type semiconductor layer such as the n⁺-type emitter layer 13. The barrier metal 5 and the emitter electrode 6 may be collectively referred to as an emitter electrode. Note that although FIG. 4 illustrates a diagram in which the interlayer insulating film 4 is not provided on the dummy trench electrode 12a of the dummy trench gate 12, the interlayer insulating film 4 may be formed on the dummy trench electrode 12a of the dummy trench gate 12. In a case where the interlayer insulating film 4 is formed on the dummy trench electrode 12a of the dummy trench gate 12, the emitter electrode 6 and the dummy trench electrode 12a only need to be electrically connected in another cross section.

A collector electrode 7 is provided on the second main surface side of the p-type collector layer 16. Similarly to the emitter electrode 6, the collector electrode 7 may include an aluminum alloy, or an aluminum alloy and a plating film. Further, the collector electrode 7 may have a configuration different from that of the emitter electrode 6. The collector electrode 7 is in ohmic contact with the p-type collector layer 16 and is electrically connected to the p-type collector layer 16.

FIG. 5 is a cross-sectional view of the semiconductor device 100 taken along broken line B-B in FIG. 3, and is a cross-sectional view of the IGBT region 10. FIG. 5 is different from the cross-sectional view taken along broken line A-A illustrated in FIG. 4 in that the n⁺-type emitter layer 13 provided on the first main surface side of the semiconductor substrate in contact with the active trench gate 11 is not seen in the cross-sectional view taken along broken line B-B in FIG. 5. That is, as illustrated in FIG. 3, the n⁺-type emitter layer 13 is selectively provided on the first main surface side of the p-type base layer. Note that the p-type base layer referred to here is a p-type base layer collectively referring to the p-type base layer 15 and the p⁺-type contact layer 14.

### (4) Example of Structure of Diode Region 20

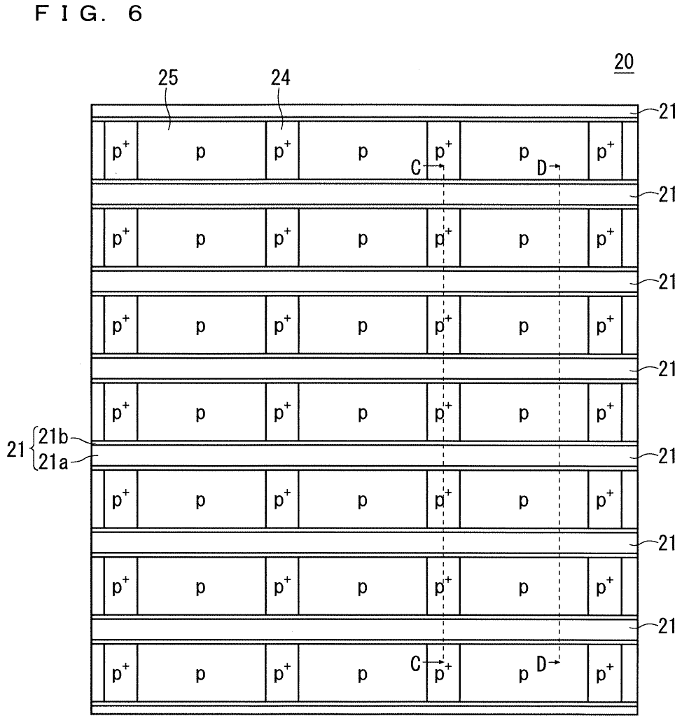

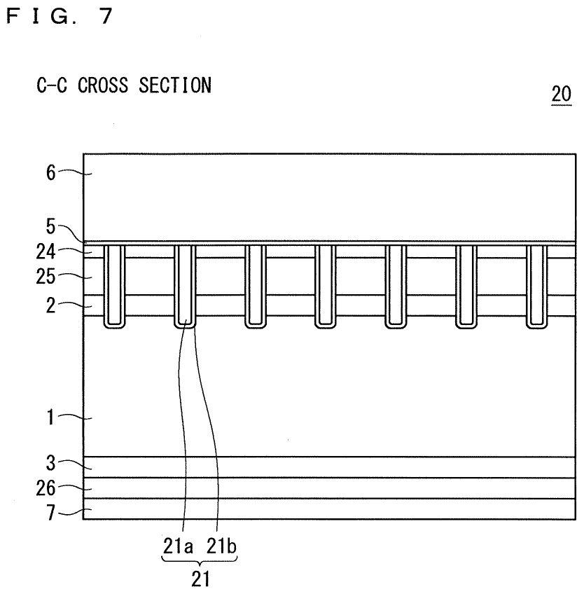

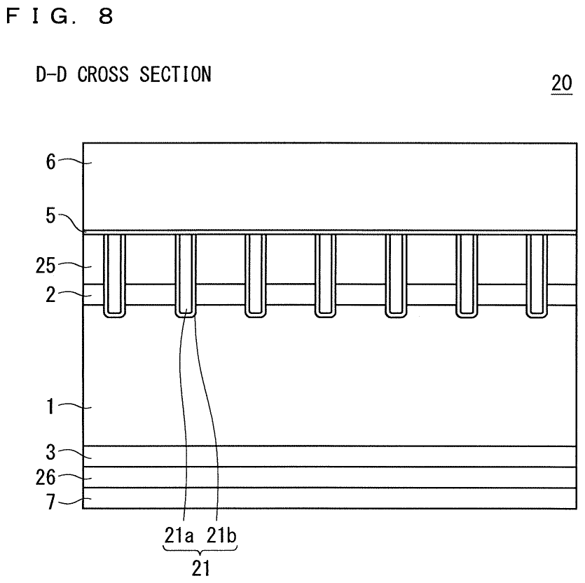

FIG. 6 is a partially enlarged plan view illustrating a configuration of a diode region of the semiconductor device which is an RC-IGBT. Further, FIGS. 7 and 8 are cross-sectional views illustrating a configuration of the diode region of the semiconductor device which is an RC-IGBT. FIG. 6 illustrates a region surrounded by a broken line 83 in the semiconductor device 100 illustrated in FIG. 1 in an enlarged manner. FIG. 7 is a cross-sectional view taken along broken line C-C of the semiconductor device 100 illustrated in FIG. 6. FIG. 8 is a cross-sectional view taken along broken line D-D of the semiconductor device 100 illustrated in FIG. 6.

A diode trench gate 21 extends along the first main surface of the semiconductor device 100 from one end side of the diode region 20, which is the cell region, toward facing another end side. The diode trench gate 21 is configured by providing a diode trench electrode 21a in a trench formed in a semiconductor substrate of the diode region 20 with a diode trench insulating film 21b interposed between them. The diode trench electrode 21a faces the n⁻-type drift layer 1 with the diode trench insulating film 21b interposed between them. A p⁺-type contact layer 24 and a p-type anode layer 25 are provided between two adjacent ones of the diode trench gates 21. The p⁺-type contact layer 24 is a semiconductor layer containing, for example, boron or aluminum as a p-type impurity, and concentration of the p-type impurity is 1.0E+15/cm³ to 1.0E+20/cm³. The p-type anode layer 25 is a semiconductor layer containing, for example, boron or aluminum as a p-type impurity, and concentration of the p-type impurity is 1.0E+12/cm³ to 1.0E+19/cm³. The p⁺-type contact layer 24 and the p-type anode layer 25 are alternately provided in a longitudinal direction of the diode trench gate 21.

FIG. 7 is a cross-sectional view of the semiconductor device 100 taken along broken line C-C in FIG. 6, and is a cross-sectional view of the diode region 20. The semiconductor device 100 also includes the n⁻-type drift layer 1 including a semiconductor substrate in the diode region 20 as in the IGBT region 10. The n-type drift layer 1 of the diode region 20 and the n-type drift layer 1 of the IGBT region 10 are continuously and integrally formed, and are formed of the same semiconductor substrate. In FIG. 7, the semiconductor substrate is a range from the p⁺-type contact layer 24 to an n⁺-type cathode layer 26. In FIG. 7, an upper end in the diagram of the p⁺-type contact layer 24 is referred to as the first main surface of the semiconductor substrate, and a lower end in the diagram of the n⁺-type cathode layer 26 is referred to as the second main surface of the semiconductor substrate. A first main surface of the diode region 20 and a first main surface of the IGBT region 10 are flush, and a second main surface of the diode region 20 and a second main surface of the IGBT region 10 are flush.

As illustrated in FIG. 7, also in the diode region 20, similarly to the IGBT region 10, the n-type carrier stored layer 2 is provided on a first main surface side of the n⁻-type drift layer 1, and the n-type buffer layer 3 is provided on a second main surface side of the n⁻-type drift layer 1. The n-type carrier stored layer 2 and the n-type buffer layer 3 provided in the diode region 20 have the same configuration as the n-type carrier stored layer 2 and the n-type buffer layer 3 provided in the IGBT region 10. Note that the n-type carrier stored layer 2 is not necessarily provided in the IGBT region 10 or the diode region 20, and even in a case where the n-type carrier stored layer 2 is provided in the IGBT region 10, the configuration may be such that the n-type carrier stored layer 2 is not provided in the diode region 20. Further, similarly to the IGBT region 10, the n-type drift layer 1, the n-type carrier stored layer 2, and the n-type buffer layer 3 may be collectively referred to as a drift layer.

The p-type anode layer 25 is provided on the first main surface side of the n-type carrier stored layer 2. The p-type anode layer 25 is provided between the n⁻-type drift layer 1 and the first main surface. The p-type anode layer 25 may have the same concentration of a p-type impurity as the p-type base layer 15 of the IGBT region 10, and the p-type anode layer 25 and the p-type base layer 15 may be formed at the same time. Further, concentration of a p-type impurity of the p-type anode layer 25 may be set to be lower than concentration of a p-type impurity of the p-type base layer 15 of the IGBT region 10 so as to reduce an amount of holes injected into the diode region 20 during diode operation. By reducing an amount of holes injected during diode operation, a recovery loss during diode operation can be reduced.

The p⁺-type contact layer 24 is provided on the first main surface side of the p-type anode layer 25. Concentration of a p-type impurity of the p⁺-type contact layer 24 may be the same as or different from concentration of a p-type impurity of the p⁺-type contact layer 14 of the IGBT region 10. The p⁺-type contact layer 24 constitutes the first main surface of the semiconductor substrate. Note that the p⁺-type contact layer 24 is a region having higher concentration of a p-type impurity than the p-type anode layer 25, and in a case where it is necessary to distinguish the p⁺-type contact layer 24 and the p-type anode layer 25 from each other, they may be referred to individually, and the p⁺-type contact layer 24 and the p-type anode layer 25 may be collectively referred to as a p-type anode layer.

In the diode region 20, the n⁺-type cathode layer 26 is provided on the second main surface side of the n-type buffer layer 3. The n⁺-type cathode layer 26 is provided between the n⁻-type drift layer 1 and the second main surface. The n⁺-type cathode layer 26 is a semiconductor layer containing, for example, arsenic or phosphorus as an n-type impurity, and concentration of the n-type impurity is 1.0E+16/cm³ to 1.0E+21/cm³. As illustrated in FIG. 2, the n⁺-type cathode layer 26 is provided in a part or all of the diode region 20. The n⁺-type cathode layer 26 constitutes the second main surface of the semiconductor substrate. Note that, although not illustrated, as described above, a p-type impurity may be further selectively implanted into a region where the n⁺-type cathode layer 26 is formed, and a p-type cathode layer may be provided using a part of a region where the n⁺-type cathode layer 26 is formed as a p-type semiconductor.

As illustrated in FIG. 7, a trench that penetrates the p-type anode layer 25 from the first main surface of the semiconductor substrate and reaches the n⁻-type drift layer 1 is formed in the diode region 20 of the semiconductor device 100. The diode trench electrode 21a is provided in a trench of the diode region 20 with the diode trench insulating film 21b interposed between them, so that the diode trench gate 21 is formed. The diode trench electrode 21a faces the n⁻-type drift layer 1 with the diode trench insulating film 21b interposed between them.

As illustrated in FIG. 7, the barrier metal 5 is provided on the diode trench electrode 21a and the p⁺-type contact layer 24. The barrier metal 5 is in ohmic contact with the diode trench electrode 21a and the p⁺-type contact layer 24, and is electrically connected to the diode trench electrode and the p⁺-type contact layer 24. The barrier metal 5 may have the same configuration as the barrier metal 5 in the IGBT region 10. An emitter electrode 6 is provided on the barrier metal 5. The emitter electrode 6 provided in the diode region 20 is formed continuously with the emitter electrode 6 provided in the IGBT region 10. Note that, as in the case of the IGBT region 10, the diode trench electrode 21a and the p⁺-type contact layer 24 may be brought into ohmic contact with the emitter electrode 6 without provision of the barrier metal 5. Note that although FIG. 7 illustrates a diagram in which the interlayer insulating film 4 is not provided on the diode trench electrode 21a of the diode trench gate 21, the interlayer insulating film 4 may be formed on the diode trench electrode 21a of the diode trench gate 21. In a case where the interlayer insulating film 4 is formed on the diode trench electrode 21a of the diode trench gate 21, the emitter electrode 6 and the diode trench electrode 21a may be electrically connected in another cross section.

The collector electrode 7 is provided on a second main surface side of the n⁺-type cathode layer 26. Similarly to the emitter electrode 6, the collector electrode 7 of the diode region 20 is formed continuously with the collector electrode 7 provided in the IGBT region 10. The collector electrode 7 is in ohmic contact with the n⁺-type cathode layer 26 and is electrically connected to the n⁺-type cathode layer 26.

FIG. 8 is a cross-sectional view of the semiconductor device 100 taken along broken line D-D in FIG. 6, and is a cross-sectional view of the diode region 20. FIG. 8 is different from the cross-sectional view taken along broken line C-C illustrated in FIG. 7 in that the p⁺-type contact layer 24 is not provided between the p-type anode layer 25 and the barrier metal 5, and the p-type anode layer 25 constitutes the first main surface of the semiconductor substrate. That is, the p⁺-type contact layer 24 illustrated in FIG. 7 is selectively provided on the first principal surface side of the p-type anode layer 25.

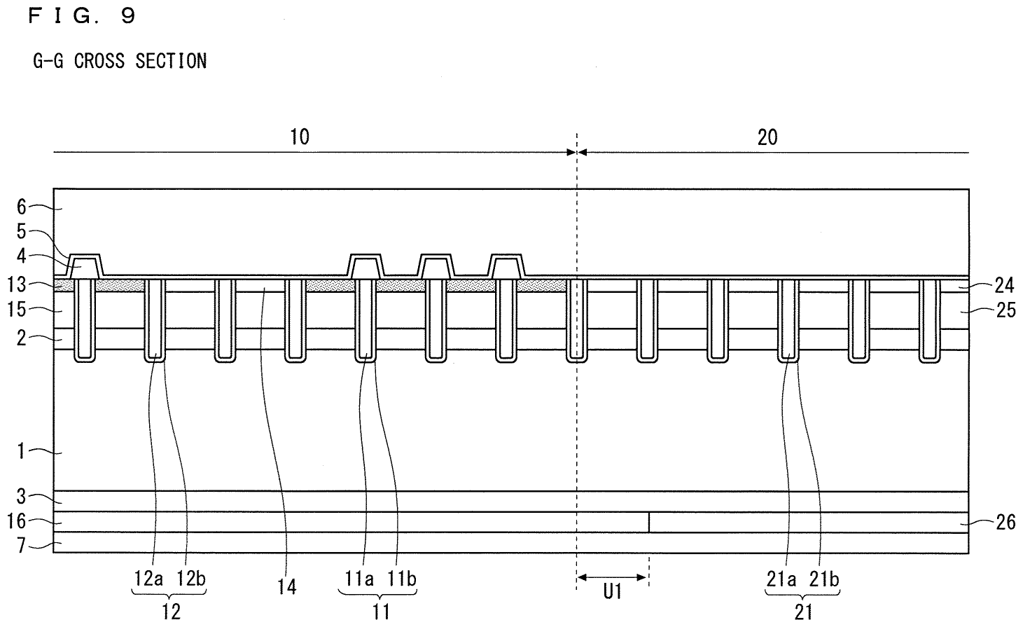

(5) Boundary Region Between IGBT Region 10 and Diode Region 20 FIG. 9 is a cross-sectional view illustrating a configuration of a boundary between an IGBT region and a diode region of the semiconductor device that is an RC-IGBT. FIG. 9 is a cross-sectional view taken along broken line G-G in the semiconductor device 100 illustrated in FIG. 1.

As illustrated in FIG. 9, the p-type collector layer 16 provided on the second main surface side of the IGBT region 10 is provided so as to protrude by a distance U1 into the diode region 20 from a boundary between the IGBT region 10 and the diode region 20. As described above, since the p-type collector layer 16 is provided so as to protrude into the diode region 20, a distance between the n⁺-type cathode layer 26 of the diode region 20 and the active trench gate 11 can be made large, and even in a case where gate drive voltage is applied to the gate trench electrode 11a during freewheeling diode operation, current can be prevented from flowing from a channel formed adjacent to the active trench gate 11 of the IGBT region 10 to the n⁺-type cathode layer 26. The distance U1 may be, for example, 100 μm. Note that the distance U1 may be zero or a distance smaller than 100 μm depending on the application of the semiconductor device 100 which is an RC-IGBT.

### (6) Structure of Gate Wiring and Gate Finger Wiring

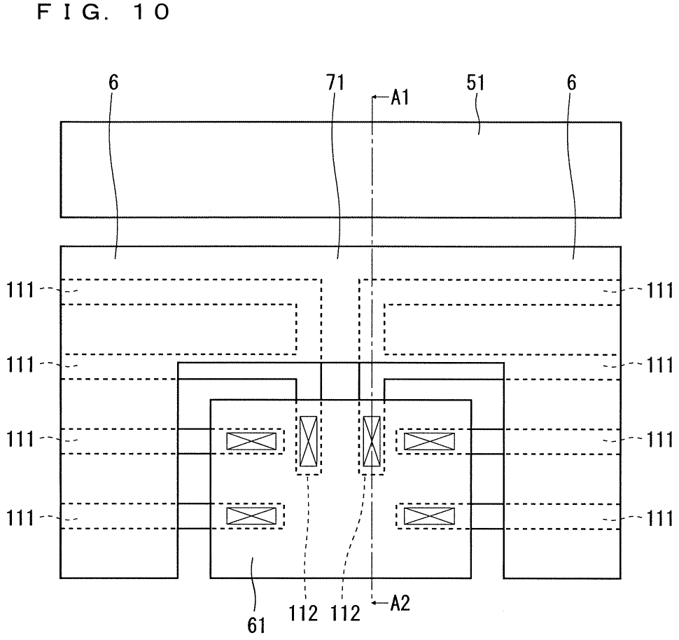

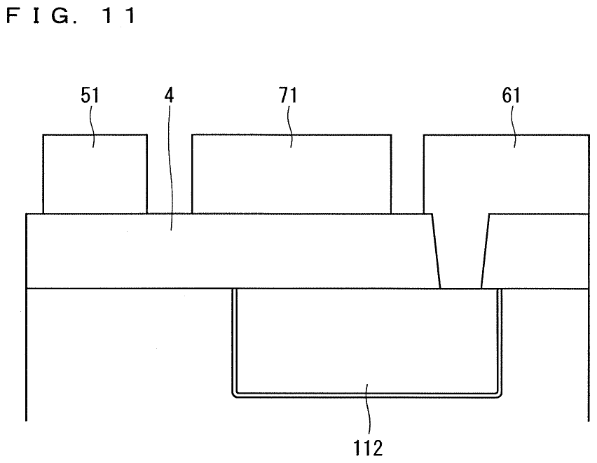

FIG. 10 is a plan view of the vicinity of the emitter electrode coupling region 70 of the semiconductor device 100 illustrated in FIG. 1 or 2. Further, FIG. 11 is a cross-sectional view taken along line A1-A2 illustrated in FIG. 10. FIGS. 10 and 11 illustrate the emitter electrode 6 which is a surface electrode arranged in the cell region, the gate wiring 51 arranged in the gate wiring region 50, the gate finger wiring 61 arranged in the gate finger wiring region 60, an emitter electrode coupling portion 71 arranged in the emitter electrode coupling region 70, and a first active trench gate 111 and a second active trench gate 112 formed in the semiconductor substrate.

The first active trench gate 111 and the second active trench gate 112 are a part of the active trench gate 11. That is, the active trench gate 11 includes the first active trench gate 111 and the second active trench gate 112. The first active trench gate 111 extends in a first direction orthogonal to an extending direction of the gate finger wiring 61. The second active trench gate 112 is electrically connected to the first active trench gate 111 and extends in a second direction parallel to the extending direction of the gate finger wiring 61. The second active trench gate 112 is extended to below the gate finger wiring 61. The first active trench gate 111 is a main part of the active trench gate 11, and the active trench gate 11 illustrated in FIGS. 3, 4, 5, and 9 corresponds to the first active trench gate 111.

As illustrated in FIG. 11, similarly to the emitter electrode 6, the gate wiring 51 and the gate finger wiring 61 are formed on the interlayer insulating film 4 (the barrier metal 5 is not illustrated in FIG. 11). The gate wiring 51 electrically connects the active trench gate 11 and the gate pad 41c. The gate finger wiring 61 is provided to be electrically connected to the gate wiring 51. Therefore, a gate signal input to the gate pad 41c is transmitted to the gate finger wiring 61 via the gate wiring 51.

Further, the gate finger wiring 61 is connected to the first active trench gate 111 and the second active trench gate 112 through a contact hole formed in the interlayer insulating film 4 (a rectangle with diagonals drawn illustrated in FIG. 10 indicates a position of the contact hole). Therefore, since a gate signal is transmitted to the active trench gate 11 not only through the gate wiring 51 but also through the gate finger wiring 61, a delay of the gate signal is suppressed.

Here, the gate finger wiring 61 cannot be directly connected to the first active trench gate 111 below the emitter electrode coupling portion 71. In the present preferred embodiment, the second active trench gate 112 extended to below the gate finger wiring 61 is connected to the first active trench gate 111 below the emitter electrode coupling portion 71, and the gate finger wiring 61 is connected to the second active trench gate 112. By the above, the gate finger wiring 61 is also electrically connected to the first active trench gate 111 below the emitter electrode coupling portion 71. For this reason, the emitter electrode coupling portion 71 is arranged so as to overlap at least a part of the second active trench gate 112.

The gate finger wiring 61 is, for example, an aluminum wiring. A material of the gate finger wiring 61 may be the same material as the emitter electrode 6, and in this case, the gate finger wiring 61 can be formed simultaneously with the emitter electrode 6. However, since the gate finger wiring 61 and the emitter electrode 6 are set to different potentials, the gate finger wiring 61 and the emitter electrode 6 are separated from each other.

As illustrated in FIG. 11, the gate finger wiring 61 is formed in the same layer as the emitter electrode 6. For this reason, the emitter electrode 6 is partitioned by the gate finger wiring 61. However, the emitter electrodes 6 adjacent to each other with the gate finger wiring 61 interposed between them are not completely divided. The emitter electrodes 6 adjacent to each other with the gate finger wiring 61 interposed between them are coupled by the emitter electrode coupling portion 71 arranged in the emitter electrode coupling region 70. A material of the emitter electrode coupling portion 71 may be the same as a material of the emitter electrode 6, and the emitter electrode 6 and the emitter electrode coupling portion 71 may be formed uniformly.

As described above, as the emitter electrodes 6 adjacent to each other with the gate finger wiring 61 interposed between them are electrically connected through the emitter electrode coupling portion 71, current imbalance is improved, and short-circuit withstand capacity of the semiconductor device 100 is improved.

### Second Preferred Embodiment

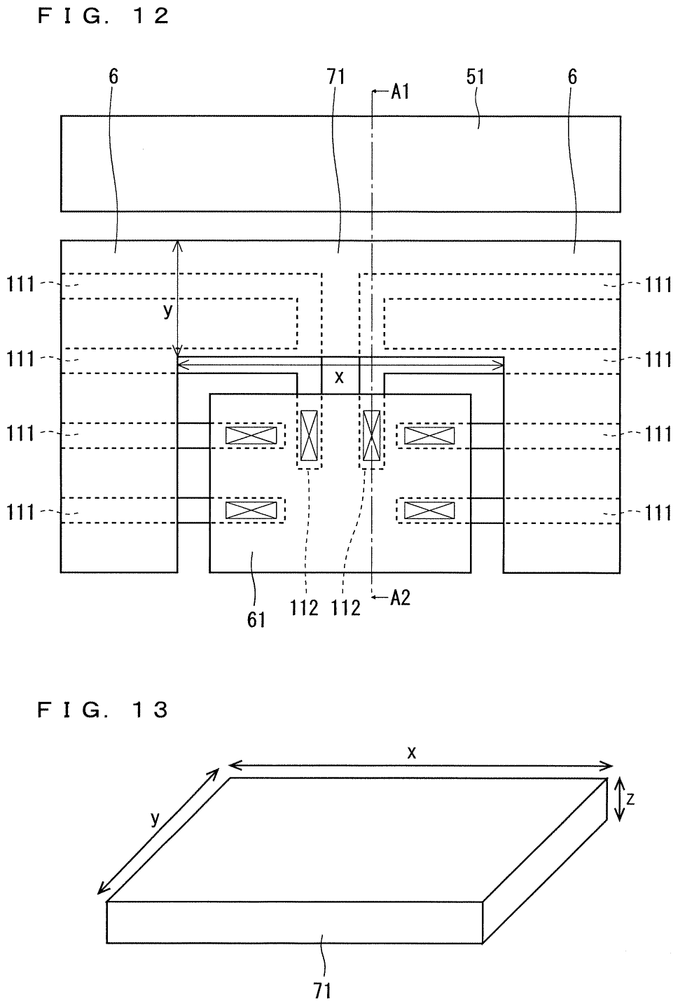

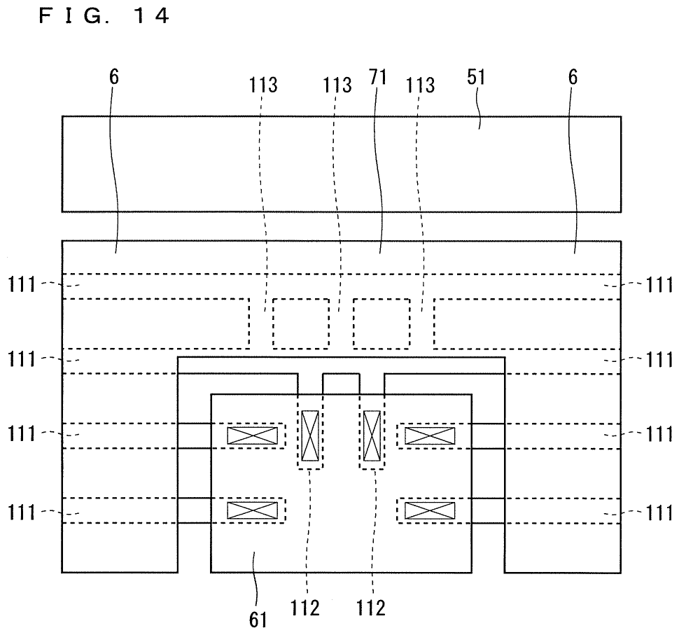

FIG. 12 is a plan view of the vicinity of the emitter electrode coupling region 70 of the semiconductor device 100 according to a second preferred embodiment. Further, FIG. 13 illustrates a shape of the emitter electrode coupling portion 71. The configuration illustrated in FIG. 12 is similar to that in FIG. 10.

As illustrated in FIGS. 12 and 13, assume that length in the first direction (direction orthogonal to an extending direction of the gate finger wiring 61) of the emitter electrode coupling portion 71 is x, length in the second direction (extending direction of the gate finger wiring 61) of the emitter electrode coupling portion 71 is y, and thickness of the emitter electrode coupling portion 71 is z. Hereinafter, x is referred to as “length” of the emitter electrode coupling portion 71, and y is referred to as “width” of the emitter electrode coupling portion 71.

As illustrated in FIG. 13, assuming that the emitter electrode coupling portion 71 is a linear conductor made from metal and having a rectangular cross section, inductance L [pH] of the emitter electrode coupling portion 71 is expressed as follows:

L=0.002×[ln(2x/(y+z))+0.2235((y+z)/x)+0.5]

and resistance R [mΩ] of the emitter electrode coupling portion 71 can be expressed as follows:

R=p×/yz(ρ:resistivity).

In the semiconductor device 100 according to the second preferred embodiment, when a pitch of the first active trench gate 111 is 2.4 μm, the length x, the width y, and the thickness z of the emitter electrode coupling portion 71 are set so as to satisfy the following relationship:

0.002×[In(2x/(y+z))+0.2235((y+z)/x)+0.5]<5.0[μH]; and ρx/yz<7.5[mΩ].

As described above, by suppressing resistance and inductance of the emitter electrode coupling portion 71, an effect of improving current imbalance in the emitter electrode 6 is improved.

Further, when a pitch of the first active trench gate 111 is 4.0 μm, the length x, the width y, and the thickness z of the emitter electrode coupling portion 71 only need to be set so that the following relationship is satisfied:

0.002×[In(2x/(y+z))+0.2235((y+z)/x)+0.5]<2.5[μH]; and ρx/yz<3.0[mΩ].

### Third Preferred Embodiment

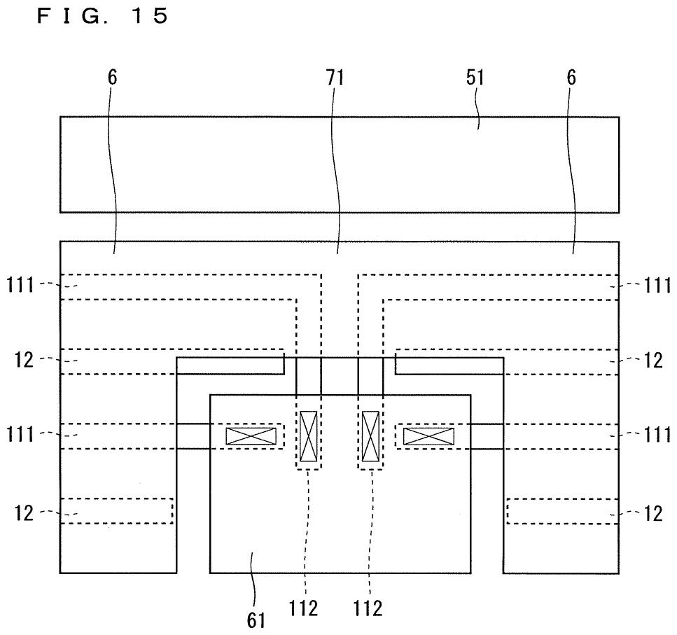

FIG. 14 is a plan view of the vicinity of the emitter electrode coupling region 70 of the semiconductor device 100 according to a third preferred embodiment.

The semiconductor device 100 according to the third preferred embodiment includes a third active trench gate 113 electrically connecting adjacent ones of the first active trench gates 111 and extending in the second direction below the emitter electrode coupling portion 71. In the example of FIG. 14, a plurality of the third active trench gates 113 are also received, and the active trench gate 11 passing below the emitter electrode coupling portion 71 has a ladder shape in plan view.

As the first active trench gates 111 below the emitter electrode coupling portion 71 are connected by the third active trench gate 113, a gate signal is easily transmitted from the gate finger wiring 61 to the first active trench gate 111 below the emitter electrode coupling portion 71, so that an effect of suppressing a gate delay is improved.

### Fourth Preferred Embodiment

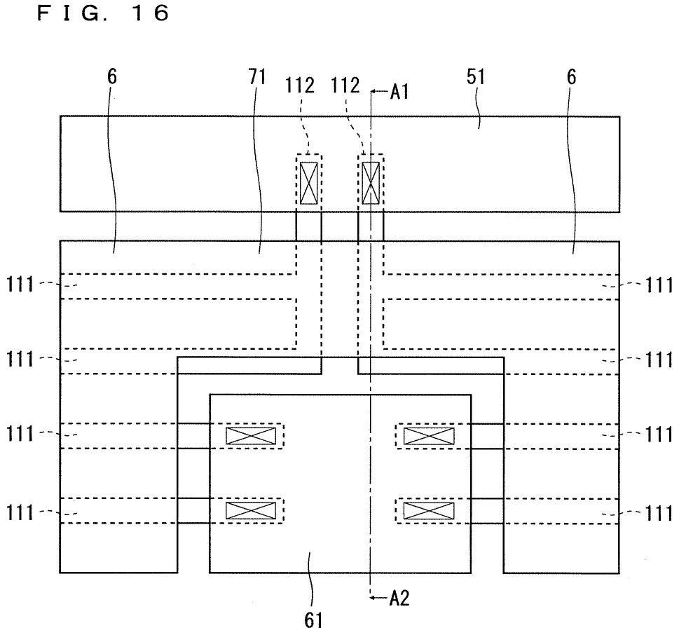

FIG. 15 is a plan view of the vicinity of the emitter electrode coupling region 70 of the semiconductor device 100 according to a fourth preferred embodiment.

The semiconductor device 100 according to the fourth preferred embodiment has a structure (gate thinning structure) obtained by thinning the active trench gate 11 by arranging the dummy trench gate 12 between the first active trench gates 111. The dummy trench gate 12 extends in parallel with the first active trench gate 111 (that is, in the first direction).

As illustrated in FIG. 15, the dummy trench gate 12 may be arranged below the emitter electrode coupling portion 71. However, when the dummy trench gate 12 intersects the second active trench gate 112, insulation between the dummy trench gate 12 and the second active trench gate 112 cannot be secured, and for this reason, the dummy trench gate 12 has a pattern interrupted at a place where the second active trench gate 112 is arranged.

Also in the present preferred embodiment, an effect similar to that of the first preferred embodiment can be obtained.

### Fifth Preferred Embodiment

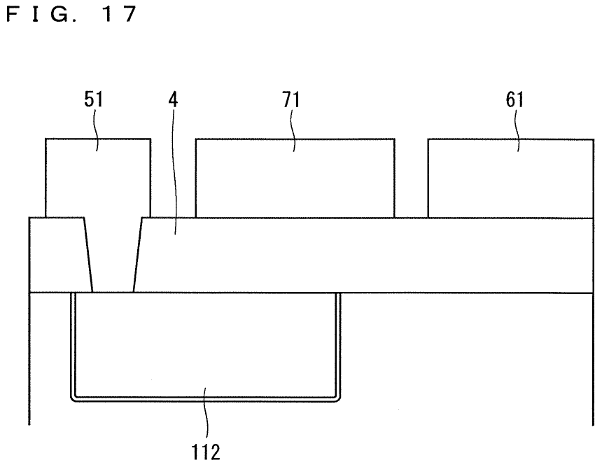

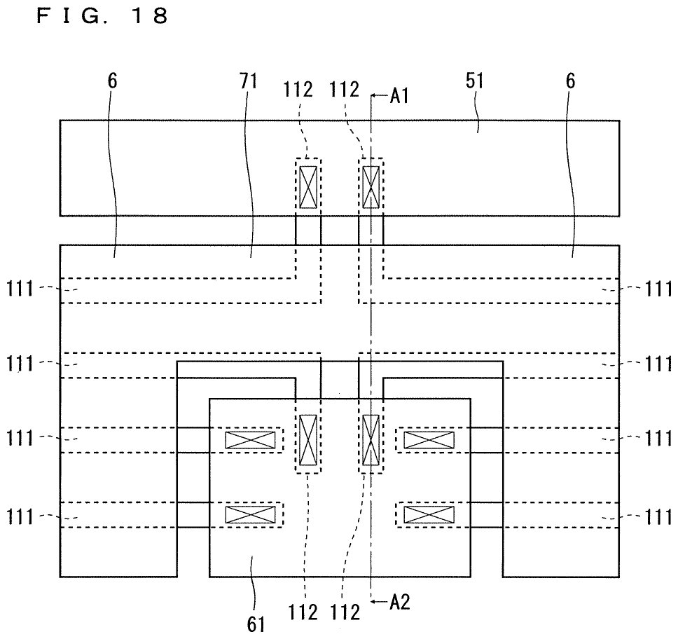

FIG. 16 is a plan view of the vicinity of the emitter electrode coupling region 70 of the semiconductor device 100 according to a fifth preferred embodiment. Further, FIG. 17 is a cross-sectional view taken along line A1-A2 illustrated in FIG. 16.

In the semiconductor device 100 according to the fifth preferred embodiment, the second active trench gate 112 connected to the first active trench gate 111 below the emitter electrode coupling portion 71 is extended to below the gate wiring 51. The gate wiring 51 is connected to the second active trench gate 112 through a contact hole formed in the interlayer insulating film 4.

Therefore, in the present preferred embodiment, the first active trench gate 111 below the emitter electrode coupling portion 71 is connected to the gate wiring 51 through the second active trench gate 112. For this reason, a gate signal is transmitted from the gate wiring 51 to the first active trench gate 111 below the emitter electrode coupling portion 71 without passing through the gate finger wiring 61.

Also in the present preferred embodiment, an effect similar to that of the first preferred embodiment can be obtained.

### Sixth Preferred Embodiment

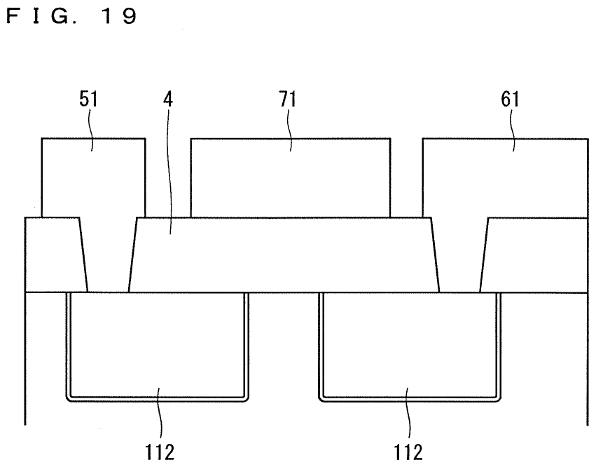

FIG. 18 is a plan view of the vicinity of the emitter electrode coupling region 70 of the semiconductor device 100 according to a sixth preferred embodiment. Further, FIG. 19 is a cross-sectional view taken along line A1-A2 illustrated in FIG. 18.

The sixth preferred embodiment is a combination of the first and fifth preferred embodiments. That is, in the semiconductor device 100 according to the sixth preferred embodiment, some of the first active trench gates 111 below the emitter electrode coupling portion 71 are connected to the second active trench gate 112 extended to below the gate finger wiring 61 as in the first preferred embodiment, and some other ones of the first active trench gate 111 are connected to the second active trench gate 112 extended to below the gate wiring 51 as in the sixth preferred embodiment.

Therefore, in the present preferred embodiment, a gate signal is transmitted from the gate wiring 51 to some of the first active trench gates 111 below the emitter electrode coupling portion 71 through the gate finger wiring 61, and a gate signal is transmitted from the gate wiring 51 to some other ones of the first active trench gates 111 without passing through the gate finger wiring 61.

With this structure, a gate signal is transmitted from both the gate wiring 51 and the gate finger wiring 61 to the first active trench gate 111 below the emitter electrode coupling portion 71, and an effect of suppressing a gate delay is improved.

### Seventh Preferred Embodiment

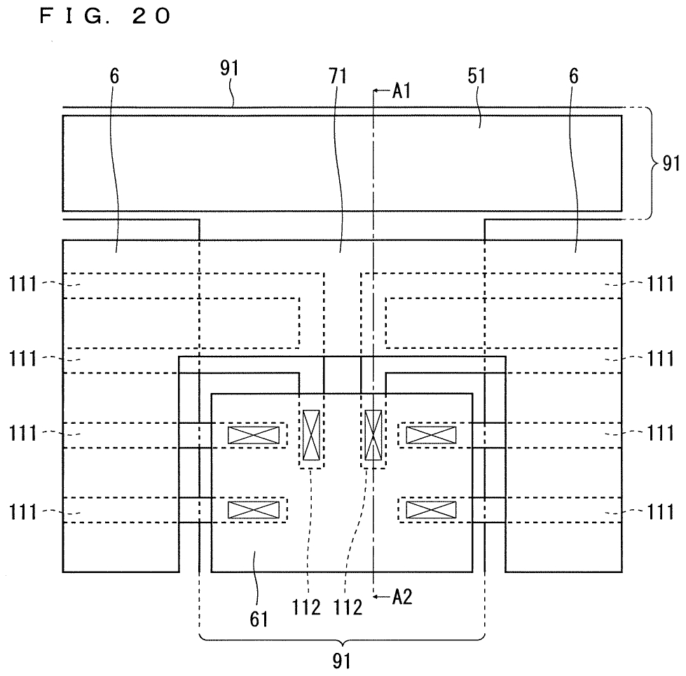

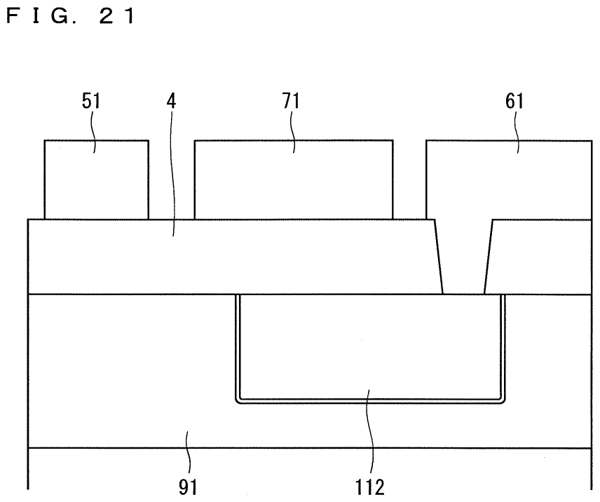

FIG. 20 is a plan view of the vicinity of the emitter electrode coupling region 70 of the semiconductor device 100 according to a seventh preferred embodiment. Further, FIG. 21 is a cross-sectional view taken along line A1-A2 illustrated in FIG. 20.

In the semiconductor device 100 according to the seventh preferred embodiment, a p-type layer 91 deeper than the first active trench gate 111 and the second active trench gate 112 is formed in a region including the emitter electrode coupling region 70 in which the emitter electrode coupling portion 71 is arranged. In a case where the p-type layer 91 is applied to the third preferred embodiment, the p-type layer 91 is formed to be deeper than the first active trench gate 111, the second active trench gate 112, and the third active trench gate 113.

With this structure, it is possible to suppress concentration of an electric field in the vicinity of an end portion of the first active trench gate 111, the second active trench gate 112, or the third active trench gate 113 located below the emitter electrode coupling portion 71.

### Eighth Preferred Embodiment

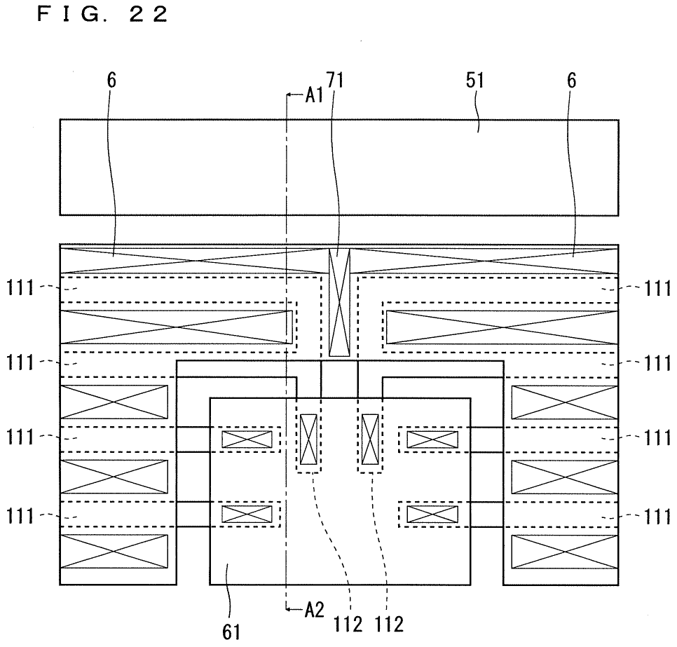

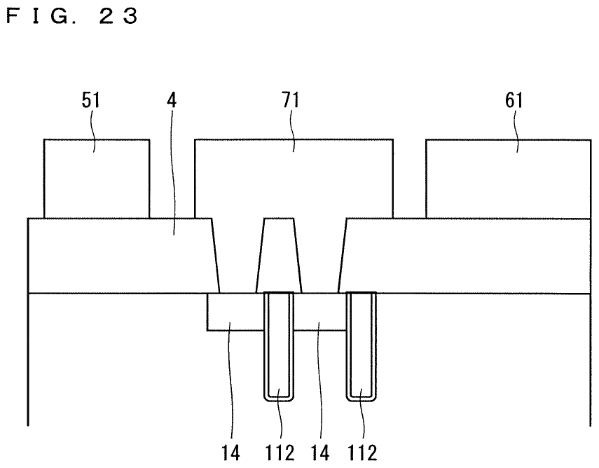

FIG. 22 is a plan view of the vicinity of the emitter electrode coupling region 70 of the semiconductor device 100 according to an eighth preferred embodiment. Further, FIG. 23 is a cross-sectional view taken along line A1-A2 illustrated in FIG. 22.

In the semiconductor device 100 according to the eighth preferred embodiment, the emitter electrode coupling portion 71 is connected to the p⁺-type contact layer 14 through a contact hole formed in the interlayer insulating film 4.

With this structure, a hole extraction effect is obtained in the emitter electrode coupling region 70, and safety operation area (SOA) tolerance of the semiconductor device 100 is improved.

### Ninth Preferred Embodiment

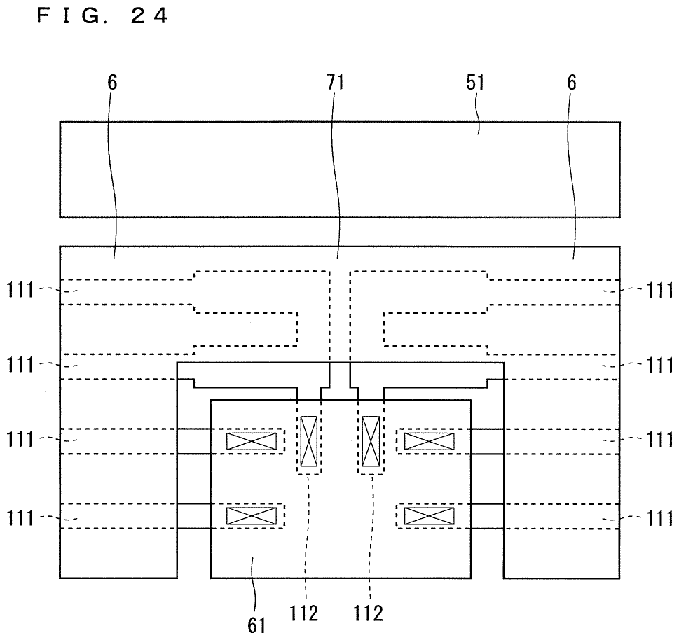

FIG. 24 is a plan view of the vicinity of the emitter electrode coupling region 70 of the semiconductor device 100 according to a ninth preferred embodiment.

In the semiconductor device 100 according to the ninth preferred embodiment, width of the active trench gate 11 (the first active trench gate 111, the second active trench gate 112, or the third active trench gate 113) arranged below the emitter electrode coupling portion 71 is wider than width in other regions. That is, width of the active trench gate 11 locally increases in a portion arranged below the emitter electrode coupling portion 71.

With this structure, gate resistance of the semiconductor device 100 is lowered, and an effect of suppressing a gate delay is improved.

### Tenth Preferred Embodiment

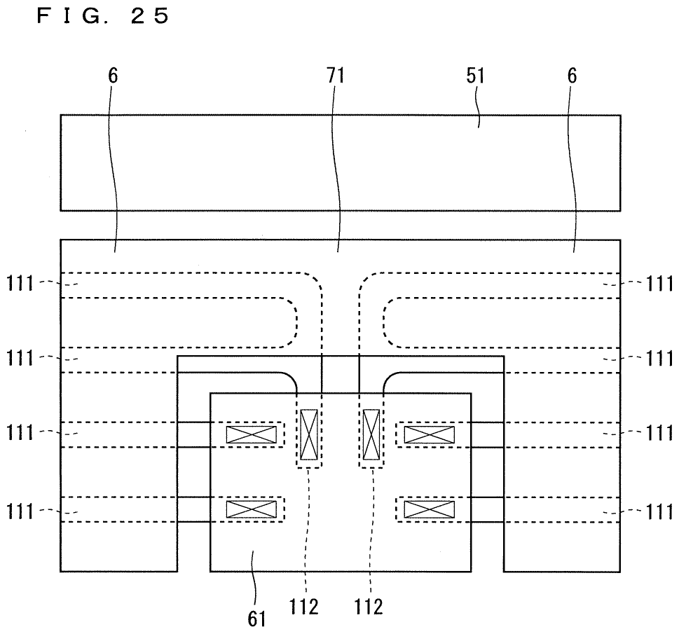

FIG. 25 is a plan view of the vicinity of the emitter electrode coupling region 70 of the semiconductor device 100 according to a tenth preferred embodiment.

In the semiconductor device 100 according to the tenth preferred embodiment, a corner portion of the active trench gate 11 (the first active trench gate 111, the second active trench gate 112, or the third active trench gate 113) arranged below the emitter electrode coupling portion 71 has a round shape (R shape).

With this structure, an electric field is prevented from concentrating at a corner portion of a trench of the active trench gate 11, and for this reason, withstand voltage and SOA tolerance of the semiconductor device 100 are improved.

### Eleventh Preferred Embodiment

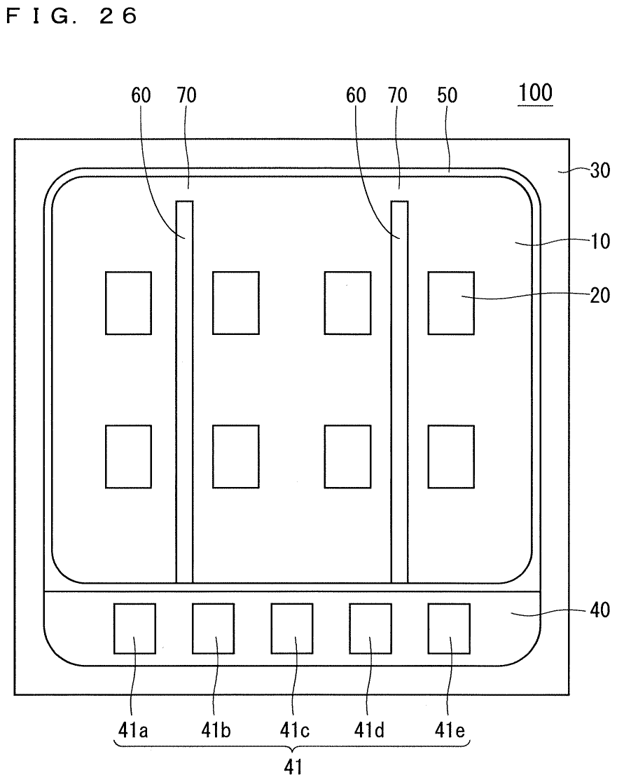

FIG. 26 is a plan view of the vicinity of the emitter electrode coupling region 70 of the semiconductor device 100 according to an eleventh preferred embodiment.

The semiconductor device 100 according to the eleventh preferred embodiment includes a plurality of the gate finger wiring regions 60 in which the gate finger wiring 61 is arranged. The emitter electrode coupling region 70 in which the emitter electrode coupling portion 71 is arranged is provided in a gap between a tip of each of a plurality of the gate finger wirings 61 and the gate wiring region 50.

The emitter electrode 6 is divided into three or more portions by a plurality of the gate finger wirings 61, and these portions are electrically connected through the emitter electrode coupling portion 71.

Since a gate signal is transmitted from a plurality of the gate finger wirings 61 to the active trench gate 11, an effect of suppressing a gate delay is improved.

### Twelfth Preferred Embodiment

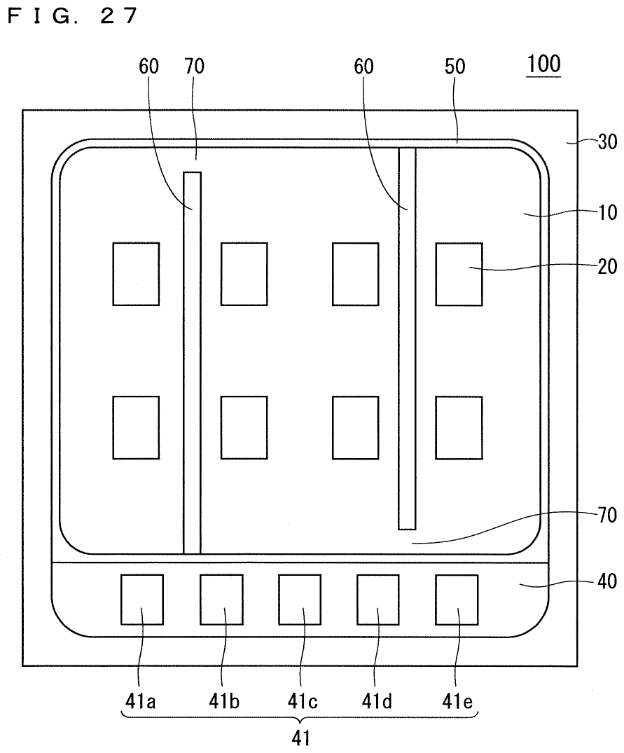

FIG. 27 is a plan view of the vicinity of the emitter electrode coupling region 70 of the semiconductor device 100 according to a twelfth preferred embodiment.

The semiconductor device 100 according to the twelfth preferred embodiment includes a plurality of the gate finger wiring regions 60 in which the gate finger wiring 61 is arranged. However, unlike the eleventh preferred embodiment, a plurality of the gate finger wirings 61 are provided side by side such that extending directions from the gate wirings 51 alternate. That is, a plurality of the gate finger wirings 61 are provided side by side such that connection portions with the gate wirings 51 are arranged in a zigzag (staggered) manner.

For example, in FIG. 27, the gate finger wiring 61 of the gate finger wiring region 60 on the left extends upward in the diagram from the side closer to the pad region 40 of the gate wiring 51, and the gate finger wiring 61 of the gate finger wiring region 60 on the right extends downward in the diagram from the side farther from the pad region 40 of the gate wiring 51. As a result, a plurality of the emitter electrode coupling regions 70 are arranged in a zigzag (staggered) manner.

Since current balance in the semiconductor device 100 is uniform as compared with the the twelfth preferred embodiment, SOA tolerance is improved.

Note that preferred embodiments can be freely combined with each other, and

each preferred embodiment can be appropriately modified or omitted.

### <Appendix>

Hereinafter, various aspects of the present disclosure will be collectively described as an appendix.

### (Appendix 1)

A semiconductor device comprising:
a plurality of active trench gates formed in a cell region of a semiconductor substrate;
an emitter electrode arranged on the cell region;
a gate wiring arranged outside the emitter electrode and electrically connected to a plurality of the active trench gates; and
a gate finger wiring electrically connected to the gate wiring and extending on the cell region, wherein
one end of the gate finger wiring is connected to the gate wiring, and another end of the gate finger wiring does not reach the gate wiring,
the emitter electrodes adjacent to each other with the gate finger wiring interposed therebetween are electrically connected to each other through an emitter electrode coupling portion arranged in a region between the another end of the gate finger wiring and the gate wiring, and
the active trench gate includes:
a first active trench gate extending in a first direction intersecting an extending direction of the gate finger wiring; and
a second active trench gate connected to the first active trench gate located below the emitter electrode coupling portion, extending in a second direction parallel to an extending direction of the gate finger wiring, and extended to below the gate finger wiring or the gate wiring.

### (Appendix 2)

The semiconductor device according to Appendix 1, wherein
a pitch of the first active trench gate is 2.4 μm, and
when length in the first direction of the emitter electrode coupling portion is x, length in the second direction of the emitter electrode coupling portion is y, thickness of the emitter electrode coupling portion is z, and resistivity of the emitter electrode coupling portion is p, a following relationship is satisfied:

0.002×[In(2x/(y+z))+0.2235((y+z)/x)+0.5]<5.0[pH]; and ρx/yz<7.5[mΩ].

### (Appendix 3)

The semiconductor device according to Appendix 1, wherein
a pitch of the first active trench gate is 4.0 μm, and
when length in the first direction of the emitter electrode coupling portion is x, length in the second direction of the emitter electrode coupling portion is y, thickness of the emitter electrode coupling portion is z, and resistivity of the emitter electrode coupling portion is p, a following relationship is satisfied:

0.002×[In(2x/(y+z))+0.2235((y+z)/x)+0.5]<2.5[μH]; and ρx/yz<3.0[mΩ].

### (Appendix 4)

The semiconductor device according to any one of Appendices 1 to 3, further comprising:
a third active trench gate electrically connecting adjacent ones of the first active trench gates and extending in the second direction below the emitter electrode coupling portion.

### (Appendix 5)

The semiconductor device according to any one of Appendices 1 to 4, further comprising:
a dummy trench gate arranged between the first active trench gates, wherein
the dummy trench gate has a pattern extending in the first direction and interrupted at a place where the second active trench gate is arranged.

### (Appendix 6)

The semiconductor device according to any one of Appendices 1 to 5, further comprising:
both the second active trench gate extended to below the gate finger wiring and the second active trench gate extended to below the gate wiring.

### (Appendix 7)

The semiconductor device according to any one of Appendices 1 to 6, wherein
a p-type layer deeper than the active trench gate is formed on the semiconductor substrate below the emitter electrode coupling portion.

### (Appendix 8)

The semiconductor device according to any one of Appendices 1 to 7, wherein
the emitter electrode coupling portion is connected to a p-type contact layer formed on the semiconductor substrate.

### (Appendix 9)

The semiconductor device according to any one of Appendices 1 to 8, wherein
width of the active trench gate is locally wide below the emitter electrode coupling portion.

### (Appendix 10)

The semiconductor device according to any one of Appendices 1 to 9, wherein
a corner portion of the active trench gate arranged below the emitter electrode coupling portion has a round shape.

### (Appendix 11)

The semiconductor device according to any one of Appendices 1 to 10, further comprising:
a plurality of the gate finger wirings.

### (Appendix 12)

The semiconductor device according to Appendix 11, wherein
a plurality of the gate finger wirings have connection portions with the gate wirings, the connection portions being arranged in a staggered manner.

While the disclosure has been shown and described in detail, the foregoing description is in all aspects illustrative and not restrictive. It is therefore understood that numerous modifications and variations can be devised.

What is claimed is:

1. A semiconductor device comprising:
a plurality of active trench gates formed in a cell region of a semiconductor substrate;
an emitter electrode arranged on the cell region;
a gate wiring arranged outside the emitter electrode and electrically connected to a plurality of the active trench gates; and
a gate finger wiring electrically connected to the gate wiring and extending on the cell region, wherein
one end of the gate finger wiring is connected to the gate wiring, and another end of the gate finger wiring does not reach the gate wiring,
the emitter electrodes adjacent to each other with the gate finger wiring interposed therebetween are electrically connected to each other through an emitter electrode coupling portion arranged in a region between the another end of the gate finger wiring and the gate wiring, and
the active trench gate includes:
a first active trench gate extending in a first direction intersecting an extending direction of the gate finger wiring; and
a second active trench gate connected to the first active trench gate located below the emitter electrode coupling portion, extending in a second direction parallel to an extending direction of the gate finger wiring, and extended to below the gate finger wiring or the gate wiring.

2. The semiconductor device according to claim 1, wherein
a pitch of the first active trench gate is 2.4 μm, and
when length in the first direction of the emitter electrode coupling portion is x, length in the second direction of the emitter electrode coupling portion is y, thickness of the emitter electrode coupling portion is z, and resistivity of the emitter electrode coupling portion is p, a following relationship is satisfied:
0.002×[In(2x/(y+z))+0.2235((y+z)/x)+0.5]<5.0[μH]; and ρx/yz<7.5[mΩ].

3. The semiconductor device according to claim 1, wherein
a pitch of the first active trench gate is 4.0 μm, and
when length in the first direction of the emitter electrode coupling portion is x, length in the second direction of the emitter electrode coupling portion is y, thickness of the emitter electrode coupling portion is z, and resistivity of the emitter electrode coupling portion is p, a following relationship is satisfied:
0.002×[In(2x/(y+z))+0.2235((y+z)/x)+0.5]<2.5[H]; and ρx/yz<3.0[mΩ].

4. The semiconductor device according to claim 1, further comprising:
a third active trench gate electrically connecting adjacent ones of the first active trench gates and extending in the second direction below the emitter electrode coupling portion.

5. The semiconductor device according to claim 1, further comprising:
a dummy trench gate arranged between the first active trench gates, wherein
the dummy trench gate has a pattern extending in the first direction and interrupted at a place where the second active trench gate is arranged.

6. The semiconductor device according to claim 1, further comprising:
both the second active trench gate extended to below the gate finger wiring and the second active trench gate extended to below the gate wiring.

7. The semiconductor device according to claim 1, wherein
a p-type layer deeper than the active trench gate is formed on the semiconductor substrate below the emitter electrode coupling portion.

8. The semiconductor device according to claim 1, wherein
the emitter electrode coupling portion is connected to a p-type contact layer formed on the semiconductor substrate.

9. The semiconductor device according to claim 1, wherein
width of the active trench gate is locally wide below the emitter electrode coupling portion.

10. The semiconductor device according to claim 1, wherein
a corner portion of the active trench gate arranged below the emitter electrode coupling portion has a round shape.

11. The semiconductor device according to claim 1, further comprising:
a plurality of the gate finger wirings.

12. The semiconductor device according to claim 11, wherein
a plurality of the gate finger wirings have connection portions with the gate wirings, the connection portions being arranged in a staggered manner.
